(19) United States
(12) Patent Application Publication
(10) Pub. No.: US 2025/0359415 A1
(43) Pub. Date: Nov. 20, 2025

(54) DISPLAY DEVICE

(71) Applicant: Samsung Display Co., Ltd., Yongin-si (KR)

(72) Inventors: TAEYOUNG SONG, Yongin-si (KR); YOUNGSOO KWON, Yongin-si (KR); KIHEON LEE, Yongin-si (KR); WON-GAP YOON, Yongin-si (KR)

(21) Appl. No.: 19/049,913

(22) Filed: Feb. 10, 2025

(30) Foreign Application Priority Data
May 20, 2024 (KR) 10-2024-0064931

(51) Int. Cl. H10H 29/851; H10H 29/80; H10K 59/38; H10K 102/00

(52) U.S. Cl. CPC H10H 29/8513; H10H 29/882; H10K 59/38; H10K 2102/331

(57) ABSTRACT

A display device includes a display panel that is configured to emit source light, and a light control layer on the display panel. The light control layer includes a partition wall, a red light control part including a first color conversion material, and a green light control part including a second color conversion material. The first color conversion material includes red quantum dots, and the second color conversion material includes green quantum dots. The partition wall includes a lower surface adjacent to the display panel and an upper surface spaced apart from the display panel with the lower surface therebetween. A second maximum distance from a reference surface parallel to the upper surface of the partition wall to the green light control part in a thickness direction may be greater than a first maximum distance from the reference surface to the red light control part.

### CROSS-REFERENCE TO RELATED APPLICATION

The present application claims priority to and the benefit of f Korean Patent Application No. 10-2024-0064931, filed on May 20, 2024, in the Korean Intellectual Property Office, the entire content of which is incorporated herein by reference.

### BACKGROUND

### 1. Field

Embodiments of the present disclosure described herein are related to a display device including quantum dots.

### 2. Description of the Related Art

A display device may be a transmissive display device configured to transmit (e.g., selectively transmit) source light generated from a light source, or be a light-emitting display device configured to generate source light independently (by itself). The display device may include different types (kinds) of light control parts (components) corresponding to individual pixels in order to generate color images. These light control parts may be configured to either transmit light with a certain wavelength range of the source light, or to convert a color of source light. Additionally, some light control parts may convert (modify) light properties without changing a color of source light. In such a display device, quantum dot materials, and/or the like, may be used for the light control parts, and there is desired or need to develop technology to improve the display quality of devices including (incorporating) quantum dots.

The above information disclosed in this Background section is only for enhancement of understanding of the background of the disclosure and therefore it may contain information that does not constitute prior art.

### SUMMARY

Aspects according to one or more embodiments of the present disclosure are directed toward a display device exhibiting excellent or suitable display quality.

Additional aspects will be set forth in part in the description which follows and, in part, will be apparent from the description, or may be learned by practice of the presented embodiments of the disclosure.

In one or more embodiments of the present disclosure a display device includes: a display panel configured to emit source light; and a light control layer arranged on the display panel, and including a partition wall, a red light control part including a first color conversion material, and a green light control part including a second color conversion material, wherein the first color conversion material includes red quantum dots, the second color conversion material includes green quantum dots, the green light control part and the red light control part are spaced and/or apart (e.g., spaced apart or separated) from each other with the partition wall therebetween in one direction normal (e.g., perpendicular) to a thickness direction, the partition wall includes a lower surface adjacent to the display panel and an upper surface spaced and/or apart (e.g., spaced apart or separated) from the display panel with the lower surface therebetween, and in the thickness direction, a second maximum distance from a reference surface (e.g., a virtual or imaginary reference surface) parallel to the upper surface of the partition wall to the green light control part is greater than a first maximum distance from the reference surface to the red light control part.

In one or more embodiments, wherein a second weight (wt %) of the second color conversion material with respect to 100 wt % of the total weight of the green light control part may be smaller than a first weight (wt %) of the first color conversion material with respect to 100 wt % of the total weight of the red light control part.

In one or more embodiments, the second weight (wt %) may be about 0.6 times or less the first weight (wt %).

In one or more embodiments, the green quantum dots may include a multi-component quantum dot containing Ag, In, Ga, and S.

In one or more embodiments, the green light control part may further include scatterers, and the scatterers are contained in an amount of about 4 wt % to about 15 wt % with respect to 100 wt % of the total weight of the green light control part.

In one or more embodiments, the green light control part and the red light control part may each further include scatterers, and a weight of the scatterers with respect to 100 wt % of the total weight of the green light control part may be greater than a weight of the scatterers with respect to 100 wt % of the total weight of the red light control part.

In one or more embodiments, the scatterers may include at least one selected from among TiO₂, SiO₂, BaTiO₃, BaO, ZnS, ZnO, Al₂O₃, and a hollow silica.

In one or more embodiments, a minimum thickness of the green light control part may be smaller than a minimum thickness of the red light control part.

In one or more embodiments, a molar extinction coefficient of the green quantum dots may be greater than a molar extinction coefficient of the red quantum dots.

In one or more embodiments, the second color conversion material may further include at least one of a green dye or a multi-component quantum dot containing In and P.

In one or more embodiments, the red quantum dots may include a multi-component quantum dot containing In and P.

In one or more embodiments, the display device may further include a color filter layer arranged on the light control layer, and including a first filter and a second filter, wherein the first filter may overlap the red light control part, and the second filter may overlap the green light control part.

In one or more embodiments, in the thickness direction, a fourth maximum distance from one surface of the color filter layer to the green light control part may be greater than a third maximum distance from the one surface of the color filter layer to the red light control part.

In one or more embodiments, a (e.g., one) surface of each of the green light control part and the red light control part may be convex or concave in the thickness direction.

In one or more embodiments, the light control layer may be directly arranged on the display panel.

In one or more embodiments, the display device may further include a color filter layer including a first filter overlapping the red light control part and a second filter overlapping the green light control part, wherein a lower surface of the color filter layer may be flat.

In one or more embodiments, the display device may further include a filling layer arranged between the display panel and the light control layer.

In one or more embodiments, the red light control part may be configured to convert the source light into red light, and the green light control part may be configured to convert the source light into green light.

In one or more embodiments of the disclosure, a display device includes: a display panel configured to emit source light; a light control layer arranged on the display panel, and including a partition wall, a green light control part including green quantum dots, and a red light control part including red quantum dots; and a color filter layer arranged on the light control layer, and including a first filter overlapping the red light control part and a second filter overlapping the green light control part, wherein the green light control part and the red light control part are spaced and/or apart (e.g., spaced apart or separated) from each other with the partition wall therebetween in one direction normal (e.g., perpendicular) to a thickness direction, and in the thickness direction, a fourth maximum distance from one surface of the color filter layer to the green light control part is greater than a third maximum distance from the one surface of the color filter layer to the red light control part.

In one or more embodiments, the green quantum dots may include a multi-component quantum dot containing Ag, In, Ga, and S.

In one or more embodiments, a weight (wt %) of the green quantum dots with respect to 100 wt % of the total weight of the green light control part may be smaller than a weight (wt %) of the red quantum dots with respect to 100 wt % of the total weight of the red light control part.

In one or more embodiments, the green light control part may further include scatterers, and the scatterers may be contained in an amount of about 4 wt % to about 15 wt % with respect to 100 wt % of the total weight of the green light control part.

In one or more embodiments, the green light control part and the red light control part may each further include scatterers, and a weight (wt %) of the scatterers with respect to 100 wt % of the total weight of the green light control part may be greater than a weight (wt %) of the scatterers with respect to 100 wt % of the total weight of the red light control part.

In one or more embodiments, the scatterers may include at least one selected from among TiO₂, SiO₂, BaTiO₃, BaO, ZnS, ZnO, Al₂O₃, and a hollow silica.

In one or more embodiments, the partition wall may include a lower surface adjacent to the display panel and an upper surface spaced and/or apart (e.g., spaced apart or separated) from the display panel with the lower surface therebetween, and in the thickness direction, a second maximum distance from an imaginary reference surface parallel to the upper surface of the partition wall to the green light control part may be greater than a first maximum distance from the reference surface to the red light control part.

### BRIEF DESCRIPTION OF THE DRAWINGS

The accompanying drawings are included to provide a further understanding of the present disclosure, and are incorporated in and constitute a part of this specification. The drawings illustrate embodiments of the disclosure and, together with the description, serve to explain principles of the disclosure. In the drawings:

FIG. 1 is a perspective view illustrating a display device according to one or more embodiments;

FIG. 2 is a cross-sectional view illustrating a portion taken along the line I-I′ of FIG. 1;

FIG. 3 is a plan view illustrating a part of a display device according to one or more embodiments;

FIG. 4 is a cross-sectional view illustrating a portion taken along the line II-II′ of FIG. 3;

FIG. 5A is an enlarged cross-sectional view of region AA′ of FIG. 4;

FIG. 5B is a cross-sectional view illustrating a part of a display device according to one or more embodiments;

FIG. 6 is a cross-sectional view illustrating a display device according to one or more embodiments;

FIG. 7 is a cross-sectional view illustrating a display device according to one or more embodiments;

FIG. 8 is a cross-sectional view illustrating a display device according to one or more embodiments;

FIG. 9 shows a graph showing a front luminance according to a content (e.g., amount) of green quantum dots;

FIG. 10 shows a graph showing a ratio of a lateral luminance to a front luminance according to a content (e.g., amount) of quantum dots;

FIG. 11 shows a graph showing an SCE reflectance and an SCI reflectance; and

FIG. 12 shows a graph showing an SCE reflectance according to a thickness of a filling layer.

### DETAILED DESCRIPTION

The present disclosure may be implemented in one or more suitable modifications and have one or more suitable forms, and specific embodiments are illustrated in the drawings and described in more detail in the text. It is to be understood, however, that the present disclosure is not intended to be limited to the particular forms disclosed, but on the contrary, is intended to cover all modifications, equivalents, and alternatives falling within the spirit and scope of the present disclosure.

In the present specification, “including A or B”, “A and/or B”, etc., represents A or B, or A and B.

As used herein, the term “and/or” includes any and all combinations of one or more of the associated listed items. As used herein, expressions such as “at least one of”, “one of”, and “selected from”, when preceding a list of elements, modify the entire list of elements and do not modify the individual elements of the list. For example, “at least one of a, b or c”, “at least one selected from a, b and c”, etc., may indicate only a, only b, only c, both (e.g., simultaneously) a and b, both (e.g., simultaneously) a and c, both (e.g., simultaneously) b and c, all of a, b, and c, or variations thereof.

In this specification, it will be understood that if (e.g., when) an element (or region, layer, portion, and/or the like) is referred to as being “on”, “connected to” or “coupled to” another element, it may be directly arranged/connected/coupled to another element, or intervening elements may be arranged therebetween.

Like reference numerals or symbols refer to like elements throughout, and duplicative descriptions thereof may not be provided. Also, in the drawings, the thicknesses, the ratios, and the dimensions of the elements are exaggerated for effective description of the technical contents. The term “and/or” includes all combinations of one or more of the associated listed elements.

Although the terms first, second, and/or the like, may be used to describe one or more suitable elements, these elements should not be limited by these terms. These terms are only used to distinguish one element from another element. For example, a first element may be referred to as a second element, and similarly, a second element may also be referred to as a first element without departing from the scope of the present disclosure. The singular forms include the plural forms as well, unless the context clearly indicates otherwise.

Also, the terms such as “below”, “lower”, “above”, “upper” and/or the like, may be used for the description to describe one element's relationship to another element illustrated in the drawings. It will be understood that the terms have a relative concept and are described on the basis of the orientation depicted in the drawings.

It will be understood that the term “includes” or “comprises”, if (e.g., when) used in this specification, specifies the presence of stated features, integers, steps, operations, elements, components, and/or a (e.g., any suitable) combination thereof, but does not preclude the presence or addition of one or more other features, integers, steps, operations, elements, components, and/or one or more (e.g., any suitable) combinations thereof.

Unless otherwise defined, all terms (including technical and scientific terms) used herein have the same meaning as commonly understood by one of ordinary skill in the art to which the present disclosure belongs. Also, terms, such as those defined in commonly used dictionaries, should be interpreted as having a meaning that is consistent with their meaning in the context of the relevant art and should not be interpreted in an idealized or overly formal sense unless expressly so defined herein.

As used herein, the term “substantially,” “about,” and similar terms are used as terms of approximation and not as terms of degree, and are intended to account for the inherent deviations in measured or calculated values that would be recognized by those of ordinary skill in the art. “Substantially” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially” may mean within one or more standard deviations, or within ±30%, 20%, 10%, 5% of the stated value.

Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

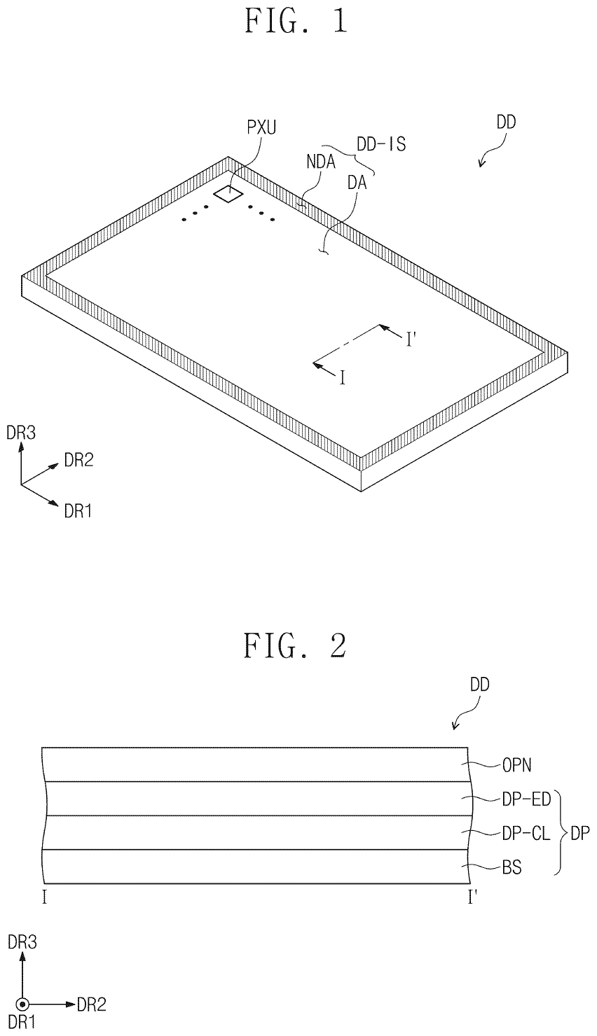

Hereinafter, a display device according to one or more embodiments of the present disclosure will be described in more detail with reference to the drawings. FIG. 1 is a perspective view illustrating a display device DD according to one or more embodiments.

Referring to FIG. 1, the display device DD according to one or more embodiments may be activated in response to an electrical signal. For example, the display device DD may be a large-sized device (be in a large-sized electronic device) such as a television, a monitor, and/or an outdoor billboard. Additionally, the display device DD may be a medium- and small-sized device (be in a medium- and small-sized electronic device) such as a personal computer, a laptop computer, a personal digital assistant, a car navigation unit, a game console, a smartphone, a tablet computer, and/or a camera. Also, these are merely presented as examples, and the display device DD may also be employed as other display devices without departing from the idea of the present disclosure. In this specification, an electronic device may be the display device DD or may include the display device DD.

The display device DD may display an image through a display surface DD-IS. The image includes not only a dynamic image but also a static image. The display surface DD-IS may be parallel to a plane defined by a first direction axis DR1 and a second direction axis DR2. The display surface DD-IS may include a display region DA and a non-display region NDA.

A unit pixel PXU may be arranged in the display region DA and may not be arranged in the non-display region NDA. The non-display region NDA may be defined along edges of the display surface DD-IS. The non-display region NDA may be around (e.g., surround) the display region DA. However, one or more embodiments of the present disclosure is not limited thereto. The non-display region NDA may not be provided, or may also be arranged on only one side of the display region DA.

FIG. 1 illustrates the display device DD provided with the flat display surface DD-IS, but one or more embodiments of the present disclosure is not limited thereto. The display device DD may also include a curved display surface or a three-dimensional display surface. The three-dimensional display surface may also include a plurality of display regions which respectively indicate different directions.

In FIG. 1 and the following drawings, the first direction axis DR1 to a third direction axis DR3 are illustrated, and directions indicated by the first to third direction axes DR1, DR2, and DR3 described herein may have a relative concept and thus may be changed to other directions. In addition, the directions indicated by the first to third direction axes DR1, DR2, and DR3 may be referred to as first to third directions, and may be denoted as the same reference numerals or symbols. In this specification, the first direction axis DR1 and the second direction axis DR2 may be orthogonal to each other, and the third direction axis DR3 may be a normal direction of a plane defined by the first direction axis DR1 and the second direction axis DR2. In this specification, a plane is referred to as the plane defined by the first direction axis DR1 and the second direction axis DR2, and a cross section is referred to as a surface which is normal (e.g., perpendicular) to the plane defined by the first direction axis DR1 and the second direction axis DR2 and is parallel to the third direction axis DR3. A thickness direction of the display device DD may be parallel to the third direction DR3 which is the normal direction of the plane defined by the first direction DR1 and the second direction DR2. In the content of the present disclosure and unless define otherwise, a plan view, refers to the view of the plane defined by the first direction axis DR1 and the second direction axis DR2. This plane is essentially the horizontal plane of the display device. The third direction axis DR3 represents the normal direction to this plane, which is perpendicular to the plane defined by DR1 and DR2. Therefore, the plan view would be a top-down view of the display device, looking along the third direction axis DR3.

In this specification, an upper surface (or front surface) and a lower surface (or rear surface) of members constituting the display device DD may be defined based on the third direction DR3. For example, in one member, among two surfaces opposite to (e.g., facing away from) each other with respect to the third direction DR3, a surface relatively adjacent to the display surface DD-IS is defined as an upper surface (or front surface), and a surface spaced and/or apart (e.g., spaced apart or separated) from the display surface DD-IS with the upper surface (or front surface) therebetween may be defined as a lower surface (or rear surface). Additionally, in this specification, an upper part (or upper side) and a lower part (or lower side) may be defined based on the third direction DR3. The upper part (or upper side) may be defined as a direction of being closer to the display surface DD-IS, and the lower part (or lower side) may be defined as a direction of being farther away from the display surface DD-IS.

In this specification, the wording, “an element is ‘directly arranged/directly formed’ on another element” refers to that intervening elements are not arranged therebetween. For example, the wording, “an element is ‘directly arranged/directly formed’ on another element” refers to that an element is ‘in contact with’ another element.

FIG. 2 is a cross-sectional view illustrating a portion taken along the line I-I′ of FIG. 1. FIG. 2 may be a cross-sectional view schematically illustrating a display device DD according to one or more embodiments.

Referring to FIG. 2, the display device DD may include a display panel DP, and an optical panel OPN arranged on the display panel DP. The display panel DP may include a base substrate BS, a circuit layer DP-CL arranged the base substrate BS, and a display element layer DP-ED arranged on the circuit layer DP-CL.

The base substrate BS may be a member which provides a base surface on which the circuit layer DP-CL and the display element layer DP-ED are arranged. The circuit layer DP-CL may include one or more insulating layers and a circuit element. The circuit element may include signal lines, a circuit for driving pixels, and/or the like. The circuit layer DP-CL may be formed through a process of forming an insulating layer, a semiconductor layer, and a conductive layer by performing coating, deposition, and/or the like, and a process of patterning the insulating layer, the semiconductor layer, and the conductive layer through photolithography.

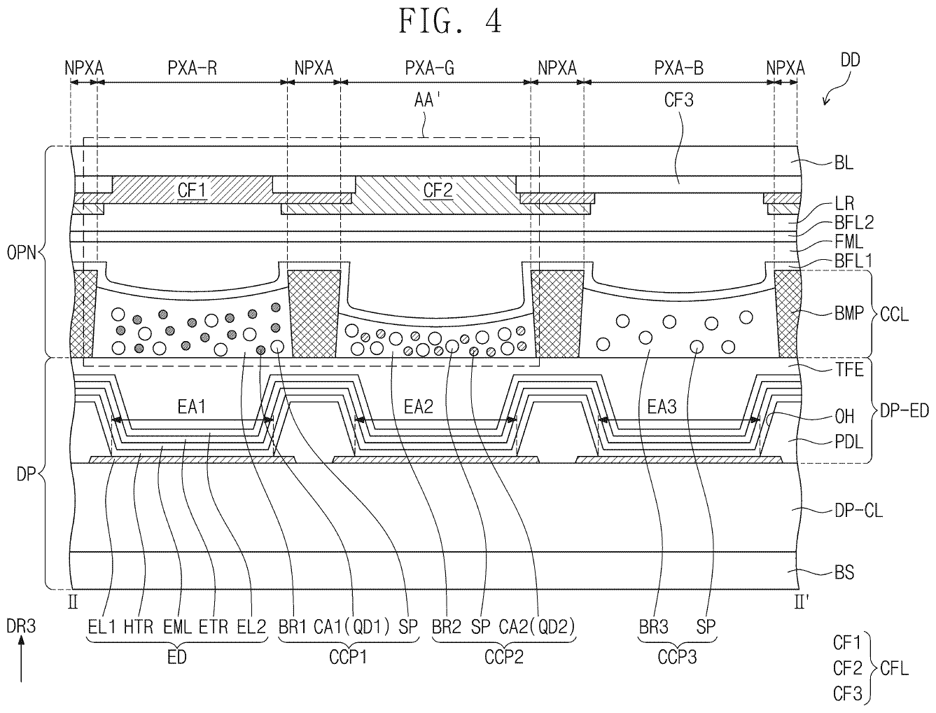

The display element layer DP-ED may include a light-emitting element ED (see FIGS. 4 and 6 to 8) to be described in more detail later. The display element layer DP-ED may provide source light emitted from the light-emitting element ED (see FIGS. 4 and 6 to 8).

The optical panel OPN may be configured to transmit the source light provided from the display element layer DP-ED of the display panel DP, and configured to convert the source light into light having a color different from that of the source light. The display device DD including the optical panel OPN may exhibit excellent or suitable display quality.

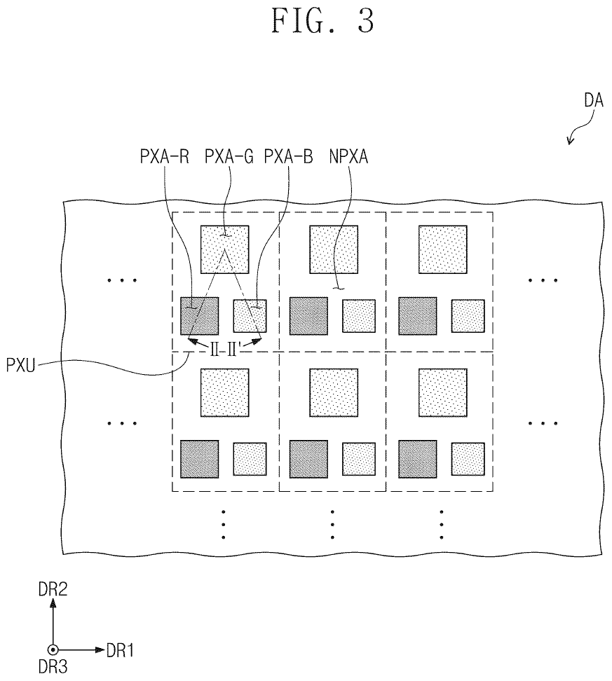

FIG. 3 is a plan view schematically illustrating a display region DA according to one or more embodiments. FIG. 3 illustrates a plane including three pixel regions PXA-R, PXA-G, and PXA-B, and a light-blocking region NPXA. The unit pixel PXU may include the first to third pixel regions PXA-R, PXA-G, and PXA-B, and the light-blocking region NPXA. The unit pixel PXU may be repeatedly arranged in the entire display region DA illustrated in FIG. 1.

The light-blocking region NPXA may be arranged around the first to third pixel regions PXA-R, PXA-G, and PXA-B. The light-blocking region NPXA may define boundaries between the first to third pixel regions PXA-R, PXA-G, and PXA-B. That is, the light-blocking region NPXA may be between the first to third pixel regions PXA-R, PXA-G, and PXA-B in a plan view. The light-blocking region NPXA may be around (e.g., surround) the first to third pixel regions PXA-R, PXA-G, and PXA-B. A structure, such as a pixel-defining film PDL (FIGS. 4 and 6 to 8) or a partition wall BMP (see FIGS. 4 and 6 to 8), which prevents color-mixing between the first to third pixel regions PXA-R, PXA-G, and PXA-B may be arranged in the light-blocking region NPXA.

FIG. 3 illustrates that the first to third pixel regions PXA-R, PXA-G, and PXA-B have the same planar shape and have different planar areas, but one or more embodiments of the disclosure is not limited thereto. At least two pixel regions among the first to third pixel regions PXA-R, PXA-G, and PXA-B may have the same area. The areas of the first to third pixel regions PXA-R, PXA-G, and PXA-B may be set according to colors of emitted light. A pixel region which is configured to emit light of a blue color among primary colors may have the smallest area.

FIG. 3 illustrates that on a plane, the first to third pixel regions PXA-R, PXA-G, and PXA-B each have a quadrilateral shape. In one or more embodiments, the first to third pixel regions PXA-R, PXA-G, and PXA-B may each have another polygonal shape such as a rhombic or pentagonal shape. In one or more embodiments, the first to third pixel regions PXA-R, PXA-G, and PXA-B may each have a quadrilateral shape with rounded corners. In one or more embodiments, the first to third pixel regions PXA-R, PXA-G, and PXA-B may have different shapes on a plane. That is, the first to third pixel regions PXA-R, PXA-G, and PXA-B may have different shapes on a plane (in a plan view) from each other.

FIG. 3 illustrates that the second pixel region PXA-G is arranged in a first row and the first pixel region PXA-R and the third pixel region PXA-B are arranged in a second row. However, this is illustrated as an example, and an arrangement of the first to third pixel regions PXA-R, PXA-G, and PXA-B may change variously. For example, the first to third pixel regions PXA-R, PXA-G, and PXA-B may be arranged in substantially the same row.

One region of the first to third pixel regions PXA-R, PXA-G, and PXA-B may be configured to emit first light, another region may be configured to emit second light different from the first light, and the other region may be configured to emit third light different from the first light and the second light. For example, the first pixel region PXA-R may be configured to emit red light, the second pixel region PXA-G may be configured to emit green light, and the third pixel region PXA-B may be configured to emit blue light. The first pixel region PXA-R may be referred to as a red pixel region, the second pixel region PXA-G may be referred to as a green pixel region, and the third pixel region PXA-B may be referred to as a blue pixel region.

FIG. 4 is a cross-sectional view illustrating a portion taken along the line II-II′ of FIG. 3. FIG. 4 may be a cross-sectional view illustrating a display device DD according to one or more embodiments.

Referring to FIG. 4, a base substrate BS may include a single layer or a plurality of layers. For example, the base substrate BS may include a three-layered structure of a polymer resin layer, an adhesive layer, and a polymer resin layer. For example, the polymer resin layer may include a polyimide-based resin. Additionally, the polymer resin layer may include at least one selected from among an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, and a perylene-based resin. In this specification, a “˜˜ based” resin is considered as including a functional group of “˜˜”. For example, a polyimide-based resin is considered as including a polyimide functional group. In the context of the present disclosure and unless define otherwise, “˜˜” is used as a placeholder to represent any suitable functional group in a chemical compound. For example, when the text mentions a “polyimide-based resin,” it means a resin that includes a polyimide functional group. Similarly, “-based resin” would refer to a resin that includes the functional group represented by “˜˜.”

The circuit layer DP-CL may include an insulating layer, a semiconductor layer, a conductive layer, a signal line, and/or the like. The circuit layer DP-CL may include a plurality of transistors. The transistors may each include a control electrode, an input (source) electrode, and an output (drain) electrode. For example, the circuit layer DP-CL may include a switching transistor and a driving transistor for driving a light-emitting element ED of a display element layer DP-ED.

The display element layer DP-ED may include the light-emitting element ED and a pixel-defining film PDL. A light-emitting opening OH may be defined in the pixel-defining film PDL. Additionally, the display element layer DP-ED may include an encapsulation layer TFE arranged on the light-emitting element ED.

The light-emitting element ED may include an organic light-emitting element and/or an inorganic light-emitting element. Additionally, the display element layer DP-ED may include an ultra-small light-emitting element. For example, the ultra-small light-emitting element may include a micro-LED element and/or a nano-LED element, and/or the like. The ultra-small light-emitting element may have a size of a micro or nano scale, and may be a light-emitting element including an active layer arranged between a plurality of semiconductor layers.

The light-emitting element ED may include a first electrode EL1, a second electrode EL2 opposite to (e.g., facing) the first electrode EL1, and a light-emitting layer EML arranged between the first electrode EL1 and the second electrode EL2. In addition, the light-emitting element ED may include a hole transport region HTR arranged between the first electrode EL1 and the light-emitting layer EML, and an electron transport region ETR arranged between the light-emitting layer EML and the second electrode EL2. In the light-emitting element ED, the light-emitting layer EML may be configured to emit source light. The source light may include blue light. FIG. 4 illustrates the light-emitting element ED including one light-emitting layer EML, but the light-emitting element ED may also include a plurality of light-emitting layers. For example, the light-emitting element ED may have a tandem structure.

At least a portion of the first electrode EL1 may be exposed from the light-emitting opening OH of the pixel-defining film PDL. The first electrode EL1 may have conductivity (e.g., may be an electron conductor). The first electrode EL1 may include (e.g., may be formed of) a metal material, a metal alloy, or a conductive compound.

The first electrode EL1 may be a cathode or an anode. However, one or more embodiments of the present disclosure is not limited thereto. Also, the first electrode EL1 may be a pixel electrode. The first electrode EL1 may be a transmissive electrode, a transflective electrode, or a reflective electrode. The first electrode EL1 may include: at least one selected from among Ag, Mg, Cu, Al, Pt, Pd, Au, Ni, Nd, Ir, Cr, Li, Ca, LiF, Mo, Ti, W, In, Sn, or Zn; a compound of two or more materials selected from there among; a mixture of two or more materials selected from there among; or an oxide thereof.

When the first electrode EL1 is the transmissive electrode, the first electrode EL1 may include a transparent metal oxide, for example, indium tin oxide (ITO), indium zinc oxide (IZO), zinc oxide (ZnO), indium tin zinc oxide (ITZO), and/or the like. When the first electrode EL1 is the transflective electrode or the reflective electrode, the first electrode EL1 may include Ag, Mg, Cu, Al, Pt, Pd, Au, Ni, Nd, Ir, Cr, Li, Ca, LiF/Ca (stacked structure of LiF and Ca), LiF/Al (stacked structure of LiF and Al), Mo, Ti, W, or a compound or mixture thereof (for example, a mixture of Ag and Mg). In one or more embodiments, the first electrode EL1 may have a multi-layered structure including a reflective film or a transflective film, which is formed of the above-described materials, and a transparent conductive film formed of indium tin oxide (ITO), indium zinc oxide (IZO), zinc oxide (ZnO), indium tin zinc oxide (ITZO), and/or the like. For example, the first electrode EL1 may have a three-layered structure of ITO/Ag/ITO, but the present disclosure is not limited thereto. Additionally, the first electrode EL1 may include the above-described metal materials, a combination of two or more metal materials selected from there among, or oxides of the above-described metal materials, and/or the like, and one or more embodiments of the present disclosure is not limited thereto.

The hole transport region HTR may be a single layer formed of a single material, and a single layer formed of a plurality of different materials, or have a multi-layered structure having a plurality of layers formed of a plurality of different materials. The hole transport region HTR may include a typical hole injection material and/or a typical hole transport material. The hole transport region HTR may include at least one selected from among a hole injection layer, a hole transport layer, and an electron blocking layer.

The light-emitting layer EML may be configured to emit source light including blue light. The light-emitting layer EML may include an organic light-emitting material and/or an inorganic light-emitting material. For example, the light-emitting layer EML may include a fluorescent light-emitting material and/or a phosphorescent light-emitting material. In one or more embodiments, the light-emitting layer EML may include quantum dots as a light-emitting material.

The electron transport region ETR may be a single layer formed of a single material, and a single layer formed of a plurality of different materials, or have a multi-layered structure having a plurality of layers formed of a plurality of different materials. The electron transport region ETR may include a typical electron injection material and/or a typical electron transport material. The electron transport region ETR may include at least one selected from among an electron injection layer, an electron transport layer, and a hole blocking layer.

FIG. 4 illustrates that the hole transport region HTR, the light-emitting layer EML, and the electron transport region ETR are provided as common layers, but one or more embodiments of the present disclosure is not limited thereto. For example, the hole transport region HTR, the light-emitting layer EML, and/or the electron transport region ETR may be provided to be patterned within the light-emitting opening OH defined in the pixel-defining film PDL.

The second electrode EL2 may be a common electrode. The second electrode EL2 may be a cathode or an anode, but one or more embodiments of the present disclosure is not limited thereto. For example, if (e.g., when) the first electrode EL1 is an anode, the second electrode EL2 may be a cathode, and if (e.g., when) the first electrode EL1 is a cathode, the second electrode EL2 may be an anode. The second electrode EL2 may include: at least one selected from among Ag, Mg, Cu, Al, Pt, Pd, Au, Ni, Nd, Ir, Cr, Li, Ca, LiF, Mo, Ti, W, In, Sn, and/or Zn; a compound of two or more materials selected from there among; a mixture of two or more materials selected from there among; or an oxide thereof.

The second electrode EL2 may be a transmissive electrode, a transflective electrode, or a reflective electrode. When the second electrode EL2 is the transmissive electrode, the second electrode EL2 may include a transparent metal oxide, for example, indium tin oxide (ITO), indium zinc oxide (IZO), zinc oxide (ZnO), indium tin zinc oxide (ITZO), and/or the like.

When the second electrode EL2 is the transflective electrode or the reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, or a compound and/or a (e.g., any suitable) mixture thereof (for example, AgMg, AgYb, or MgYb). In one or more embodiments, the second electrode EL2 may have a multi-layered structure including a reflective film or a transflective film, which is formed of the above-described materials, and a transparent conductive film formed of indium tin oxide (ITO), indium zinc oxide (IZO), zinc oxide (ZnO), indium tin zinc oxide (ITZO), and/or the like. For example, the second electrode EL2 may include the above-described metal materials, a combination of two or more metal materials selected from there among, oxides of the above-described metal materials, and/or the like.

In one or more embodiments, an element capping layer may be provided on the second electrode EL2. The element capping layer may be a single layer or a plurality of layers. The element capping layer may include an alkali metal compound such as LiF, an alkaline earth metal compound such as MgF₂, and an inorganic material such as SiON, SiNₓ, or SiO_{y}. In one or more embodiments, the element capping layer may include α-NPD, NPB, TPD, m-MTDATA, Alq₃, CuPc, N4,N4,N4′,N4′-tetra(biphenyl-4-yl) biphenyl-4,4′-diamine (TPD15), 4,4′,4″-tris(carbazol-9-yl)triphenylamine (TCTA), and/or the like, or may include an epoxy resin or an organic material, for example acrylate, and/or the like, such as methacrylate.

The pixel-defining film PDL may be formed of a polymer resin. For example, the pixel-defining film PDL may be formed of a polyacrylate-based resin or a polyimide-based resin. Additionally, the pixel-defining film PDL may further include an inorganic material in addition to a polymer resin. In one or more embodiments, the pixel-defining film PDL may be formed of a light-absorbing material, or formed of a black pigment or a black dye. The pixel-defining film PDL formed of a black pigment or a black dye may constitute a black pixel-defining film. When forming the pixel-defining film PDL, carbon black, and/or the like, may be used as a black pigment or a black dye, but one or more embodiments of the present disclosure is not limited thereto.

Additionally, the pixel-defining film PDL may be formed of an inorganic material. For example, the pixel-defining film PDL may be formed of an inorganic material such as silicon nitride (SiNₓ), silicon oxide (SiOₓ), and silicon nitride (SiOₓN_{y}).

First to third light-emitting regions EA1, EA2, and EA3 may be defined by the light-emitting opening OH of the pixel-defining film PDL. The first light-emitting region EA1, the second light-emitting region EA2, and the third light-emitting region EA3 may be regions separated by the pixel-defining film PDL. That is, the pixel-defining film PDL may be between the first light-emitting region EA1, the second light-emitting region EA2, and the third light-emitting region EA3. The first light-emitting region EA1, the second light-emitting region EA2, and the third light-emitting region EA3 may respectively correspond to the first pixel region PXA-R, the second pixel region PXA-G, and the third pixel region PXA-B. The light-emitting regions EA1, EA2, and EA3 may overlap the pixel regions PXA-R, PXA-G, and PXA-B, and may not overlap the light-blocking region NPXA. On a plane, the areas of the light-emitting regions EA1, EA2, and EA3 may be smaller than the areas of the pixel regions PXA-R, PXA-G, and PXA-B. In this specification, it will be understood that if (e.g., when) an element is referred to as overlapping another element, it is not limited to a case of having the same area and shape, and also includes a case of having different areas and/or shapes.

The display element layer DP-ED may include the encapsulation layer TFE arranged on the second electrode EL2. The encapsulation layer TFE may cover the light-emitting element ED. The encapsulation layer TFE may be a thin-film encapsulation layer. The encapsulation layer TFE may be a single layer or have a stacked structure of a plurality of layers. The encapsulation layer TFE may include at least one insulating layer. The encapsulation layer TFE may include at least one inorganic film (hereinafter, inorganic encapsulation film). Additionally, the encapsulation layer TFE may include at least one organic film (hereinafter, organic encapsulation film) and at least one inorganic encapsulation film.

The inorganic encapsulation film protects the light-emitting element ED against moisture and/or oxygen, and the organic encapsulation film protects the light-emitting element ED against foreign substances such as dust particles. The inorganic encapsulation film may include silicon nitride, silicon oxynitride, silicon oxide, titanium oxide, aluminum oxide, and/or the like, and is not particularly limited thereto. The organic encapsulation film may include an acrylate-based compound, an epoxy-based compound, and/or the like. The organic encapsulation film may include a photopolymerizable organic material, and is not particularly limited.

An optical panel OPN may be arranged on the encapsulation layer TFE. The optical panel OPN may include a light control layer CCL and a color filter layer CFL arranged on the light control layer CCL. In addition, the optical panel OPN may further include a first barrier layer BFL1, a second barrier layer BFL2, a filling layer FML, a low-refractive-index layer LR, and an upper substrate BL.

The light control layer CCL may be arranged on a display panel DP. The light control layer CCL may be directly arranged on the display panel DP. The light control layer CCL may be directly arranged on the encapsulation layer TFE of the display panel DP. However, one or more embodiments of the present disclosure is not limited thereto, and an additional member may be arranged between the display panel DP and the light control layer CCL.

The light control layer CCL may include a partition wall BMP, and first to third light control parts CCP1, CCP2, and CCP3. The first to third light control parts CCP1, CCP2, and CCP3 may be spaced and/or apart (e.g., spaced apart or separated) from each other in one direction normal (e.g., perpendicular) to the thickness direction DR3. The first light control part CCP1 may be referred to as a red light control part, and the second light control part CCP2 may be referred to as a green light control part.

The first light control part CCP1 may be provided so as to correspond to the first pixel region PXA-R, the second light control part CCP2 may be provided so as to correspond to the second pixel region PXA-G, and the third light control part CCP3 may be provided so as to correspond to the third pixel region PXA-B. The first to third light control parts CCP1, CCP2, and CCP3 may be spaced and/or apart (e.g., spaced apart or separated) from each other in one direction normal (e.g., perpendicular) to the thickness direction DR3. The partition wall BMP may be arranged between the light control parts CCP1, CCP2, and CCP3 spaced and/or apart (e.g., spaced apart or separated) from each other. However, one or more embodiments of the present disclosure is not limited thereto, and at least a portion of edges of the light control parts CCP1, CCP2, and CCP3 may overlap the partition wall BMP.

The partition wall BMP may include a base resin and an additive. The base resin may be composed of one or more suitable resin compositions generally referred to as a binder. The additive may include a coupling agent and/or a photoinitiator. The additive may further include a dispersant.

The partition wall BMP may include a black coloring agent to block light. The partition wall BMP may include a black pigment and/or a black dye mixed in the base resin. The black coloring agent may include carbon black, or include a metal such as chromium or oxide(s) thereof.

The first to third light control parts CCP1, CCP2, and CCP3 may convert source light provided from the display element layer DP-ED into light having a color different from that of the source light, or transmit source light. The third light control part CCP3 may be configured to transmit the source light provided from the display element layer DP-ED. The third light control part CCP3 may not include (e.g., may exclude) a color conversion material.

The first light control part CCP1 may include a first color conversion material CA1, and the first color conversion material CA1 may convert the source light provided from the display element layer DP-ED into first light. The first light may be red light. The first color conversion material CA1 may include first quantum dots QD1. The first quantum dot QD1 may be a red quantum dot. For example, the first quantum dot QD1 may be a multi-component quantum dot containing In and P.

The second light control part CCP2 may include a second color conversion material CA2, and the second color conversion material CA2 may be configured to convert the source light provided from the display element layer DP-ED into second light. The second light may be green light. The second color conversion material CA2 may include second quantum dots QD2. The second quantum dot QD2 may be a green quantum dot. In one or more embodiments, the second quantum dot QD2 may include a multi-component quantum dot containing Ag, In, Ga, and S. The molar extinction coefficient of the multi-component quantum dot containing Ag, In, Ga, and S is greater than the molar extinction coefficient of the multi-component quantum dot containing In and P. Hereinafter, “multi-component quantum dot containing Ag, In, Ga, and S” will be referred to as an “AIGS quantum dot”.

In one or more embodiments, the second weight (unit: wt %) of the second color conversion material CA2 included in the second light control part CCP2 with respect to 100 wt % of the total weight of the second light control part CCP2 may be smaller than the first weight (unit: wt %) of the first color conversion material CA1 included in the first light control part CCP1 with respect to 100 wt % of the total weight of the first light control part CCP1. The second weight (wt %) may be about 0.6 times or less the first weight (wt %). The weight (wt %) of the second quantum dots QD2, which are green quantum dots, with respect to the total weight of the second light control part CCP2 may be smaller than the weight (wt %) of the first quantum dots QD1, which are red quantum dots, with respect to the total weight of the first light control part CCP1.

The second light control part CCP2 includes the AIGS quantum dots, and the AIGS quantum dots have a relatively high molar extinction coefficient. Because the AIGS quantum dots have a high degree of light absorption per unit mole, the AIGS quantum dots may be configured to absorb a relatively large amount of source light to convert the source light into a relatively large amount of green light. The AIGS quantum dots have a molar extinction coefficient greater than that of the multi-component quantum dots containing In and P, and thus the second color conversion material CA2 including the AIGS quantum dots may be provided in a relatively smaller weight (wt %). The second color conversion material CA2 includes the AIGS quantum dots, and thus the second light control part CCP2 may exhibit an optical conversion property at a level equivalent to or higher than that of the first light control part CCP1 even if (e.g., when) the second color conversion material CA2 is provided in a smaller weight than the first color conversion material CA1.

In this specification, quantum dots are considered as crystals of a semiconductor compound. Hereinafter, the description of quantum dots may be similarly applied to the first and second quantum dots QD1 and QD2. The quantum dots may be configured to emit light having one or more suitable wavelength ranges by changing a crystal size and/or a ratio of elements in a compound. The quantum dots may be synthesized through a wet chemical process, a metal organic chemical vapor deposition process, a molecular beam epitaxy process, or processes similar thereto. The wet chemical process is a method of growing quantum dot particle crystals after mixing an organic solvent and a precursor material. The organic solvent naturally functions as a dispersing agent coordinated on surfaces of the quantum dot crystals during growth of the crystals, and control the growth of the crystals. Accordingly, the wet chemical process may control the growth of the quantum dot particles more easily and inexpensively than a vapor deposition method such as a metal organic chemical vapor deposition (MOCVD) or a molecular beam epitaxy (MBE).

A quantum dot may include a core and a shell around (e.g., surrounding) the core. Additionally, a quantum dot may further include a ligand bonded to a surface of a shell. The ligand may include a ligand material suitable to those in the art. The ligand may eliminate a defect, and/or the like, in a core and/or a shell and increase the stability of the quantum dot. In one or more embodiments, the quantum dot may have a single structure in which concentration of respective elements included in the quantum dot are substantially uniform.

The core of the quantum dot may include: at least one selected from among a group II-VI semiconductor compound, a group I-II-VI semiconductor compound, a group II-IV-VI compound, a group I-II-IV-VI semiconductor compound, a group III-V semiconductor compound, a group III-II-V semiconductor compound, a group III-VI semiconductor compound, a group I-III-VI semiconductor compound, a group IV-VI semiconductor compound, a group II-IV-V semiconductor compound, a group IV semiconductor compound, and a group IV element; a mixture of two or more materials selected from there among; or a compound of two or more materials selected from there among. In this specification, “the group” is referred to as a group of the IUPAC periodic table.

For example, the group II-VI semiconductor compound may include: a binary compound such as CdS, CdSe, CdTe, ZnS, ZnSe, ZnTe, ZnO, HgS, HgSe, HgTe, MgSe, and MgS; a ternary compound such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, and MgZnS; a quaternary compound such as CdZnSeS, CdZnSeTe, CdZnSTe, CdHgSeS, CdHgSeTe, CdHgSTe, HgZnSeS, HgZnSeTe, and HgZnSTe; or any combination thereof.

In one or more embodiments, the group II-VI semiconductor compound may further include a group I metal and/or a group IV element. The group I-II-VI compound may be selected from among CuSnS and CuZnS, and the group II-IV-VI compound may be selected from among ZnSnS, and/or the like. The group I-II-IV-VI compound may be selected from among a quaternary compound selected from among the group consisting of Cu₂ZnSnS₂, Cu₂ZnSnS₄, Cu₂ZnSnSe₄, Ag₂ZnSnS₂, and/or a (e.g., any suitable) mixture thereof.

For example, the group III-V semiconductor compound may include: a binary compound such as GaN, GaP, GaAs, GaSb, AlN, AlP, AlAs, AlSb, InN, InP, InAs, and InSb; a ternary compound such as GaNP, GaNAs, GaNSb, GaPAs, GaPSb, AlNP, AlNAs, AlNSb, AlPAs, AlPSb, InGaP, InNP, InAlP, InNAs, InNSb, InPAs, and InPSb; and a quaternary compound such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, and InAlPSb; or any combination thereof. In one or more embodiments, the group III-V semiconductor compound may further include a group II element. For example, the group III-V semiconductor compound further including the group II element may include InZnP, InGaZnP, InAlZnP, and/or the like.

For example, the group III-VI semiconductor compound may include: a binary compound such as GaS, Ga₂S₃, GaSe, GazSes, GaTe, InS, InSe, In₂S₃, In₂Se₃, and InTe; a ternary compound such as InGaS₃ and InGaSe₃; or any combination thereof.

For example, the group I-III-VI semiconductor compound may include: a ternary compound such as AgInS, AgInS₂, AgInSe₂, AgGaS, AgGaS₂, AgGaSe₂, CuGaS₂, CuInS, CuInS₂, CuInSe, CuGaS, CuGaSe, CuGaO₂, AgGaO₂, and AgAlO₂; a quaternary compound such as AgInGaS₂, AgInGaSe₂, CuInGaS₂, CuGaSeS, CuInGaS, and CuInGaSe; a pentanary compound such as CuInGaSeS; or any combination thereof.

For example, the group IV-VI semiconductor compound may include: a binary compound such as SnS, SnSe, SnTe, PbS, PbSe, and PbTe; a ternary compound such as SnSeS, SnSeTe, SnSTe, PbSeS, PbSeTe, PbSTe, SnPbS, SnPbSe, and SnPbTe; a quaternary compound such as SnPbSSe, SnPbSeTe, and SnPbSTe; or any combination thereof.

For example, the group II-IV-V semiconductor compound may be a ternary compound selected from among the group consisting of ZnSnP, ZnSnP₂, ZnSnAs₂, ZnGeP₂, ZnGeAs₂, CdSnP₂, and CdGeP₂, and/or a (e.g., any suitable) mixture thereof.

The group VI element or compound may include: a single element compound such as Si and Ge; a binary compound such as SiC and SiGe; or any combination thereof.

In the quantum dot, a material included in a core may differ from a material included in a shell. The shell may function as a protective layer for maintaining semiconductor properties by preventing or reducing chemical modification of the core and/or as a charging layer for imparting electrophoretic properties to the quantum dot. The shell may include a single layer or a plurality of layers. The quantum dot may have a concentration gradient in which the concentration of an element present in the shell decreases toward the core.

For example, the shell may include a metal or non-metal oxide, a semiconductor compound, and/or one or more (e.g., any suitable) combinations thereof. For example, the metal or non-metal oxide may include: a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, and NiO; a ternary compound such as MgAl₂O₄, CoFe₂O₄, NiFe₂O₄, and CoMn₂O₄, or any combination thereof. For example, as described above in this specification, the semiconductor compound may include: a group III-VI semiconductor compound; a group II-VI semiconductor compound; a group III-V semiconductor compound; a group III-VI semiconductor compound; a group I-III-VI semiconductor compound; a group IV-VI semiconductor compound; or any combination thereof. For example, the semiconductor compound may include CdS, CdSe, CdSeS, CdTe, ZnS, ZnSe, ZnTe, ZnSeS, ZnTeS, GaAs, GaP, GaS, GaSe, AgGaS, AgGaS₂, GaSb, HgS, HgSe, HgTe, InAs, InP, InGaP, InSb, AlAs, AlP, AlSb, or any combination thereof.

Elements, included in a multi-element compound, such as a binary compound, a ternary compound, and a quaternary compound, may each be present in a particle at a substantially uniform concentration or a substantially non-uniform concentration. For example, the above-described Chemical Formula may represent types (kinds) of elements included in a compound, and an element ratio within the compound may vary. For example, AgInGaS₂ may be referred to as A_{g}InₓGa₁₋ₓS₂ (x is a real number of 0 or 1).

The quantum dot may have, in an emission spectrum, a full width of half maximum (FWHM) of about 45 nm or less, about 40 nm or less, or about 30 nm or less, and within this range, a color purity or color gamut may be improved. Additionally, light emitted through the above-described quantum dots is emitted in all directions, and thus a wide viewing angle may be improved. For example, the quantum dot may have a spherical shape, a pyramidal shape, a multi-arm shape, or may be in a shape of a cubic nanoparticle, a nanotube, nanowire, a nanofiber, a nanoplate-shaped particle, and/or the like.

An energy band gap of a quantum dot may be controlled or selected by adjusting a size of the quantum dot or an element ratio within a compound forming the quantum dot, and thus light having one or more suitable wavelengths may be obtained from the light control layer CCL including the quantum dot.

First to third light control parts CCP1, CCP2, and CCP3 may each include scatterers SP. The scatterers SP may be an inorganic particle. For example, the scatterers SP may include at least one selected from among TiO₂, SiO₂, BaTiO₃, BaO, ZnS, ZnO, Al₂O₃, and a hollow silica. The scatterers SP may include any one selected from among TiO₂, SiO₂, BaTiO₃, BaO, ZnS, ZnO, Al₂O₃, and a hollow silica, and/or a (e.g., any suitable) mixture of two or more materials selected from among TiO₂, SiO₂, BaTiO₃, BaO, ZnS, ZnO, Al₂O₃, and a hollow silica.

The scatterers SP may be contained in an amount of about 4 wt % to about 15 wt % with respect to 100 wt % of the total weight of the second light control part CCP2. The weight of the scatterers SP with respect to the total weight of the second light control part CCP2 may be greater than the weight of the scatterers SP with respect to the total weight of the first light control part CCP1. The second light control part CCP2 includes a relatively smaller weight of the second color conversion material CA2, but includes a relatively greater weight of the scatterers SP, and thus white angle dependency (WAD) may be maintained at a favorable level. The WAD refers to color variations at a lateral viewing angle, that is, a phenomenon in which a color viewed if (e.g., when) a surface which is configured to emit light is seen from a front surface differs from a color if (e.g., when) the surface which is configured to emit light is seen from a lateral surface. For example, the WAD refers to a phenomenon in which white light is viewed if (e.g., when) a display surface, of a display device, emitting white light is seen from a front surface, but a blue or yellow component is partially viewed due to light wavelength variation if (e.g., when) the display surface is viewed from a lateral surface. The scatterers SP may be particles which scatter and diffuse light. Accordingly, the second light control part CCP2 including a relatively greater weight of the scatterers SP improves light-scattering, and thus the WAD may be maintained at a favorable level. The second light control part CCP2 including the scatterers SP satisfying the above-described weight range (that is, about 4 wt % to about 15 wt %) may exhibit an excellent or suitable optical property. In contrast, the second light control part including scatterers of less than about 4 wt % with respect to the total weight thereof deteriorates display quality because light scattering and diffusion is insufficient. The second light control part including scatterers of greater than about 15 wt % with respect to the total weight thereof deteriorates display quality due to an excessive increase in reflectance, and it is not easy to form the second light control part. Because a material including an excessive or greater amount of (that is, greater than bout 15 wt %) scatterers has a high viscosity, the material is unsuited (e.g., not suitable) to be provided through inkjet printing method and dispensing during the forming of the second light control part.

The light control part is formed by providing a liquid composition, and the liquid composition is provided through inkjet printing or dispensing. The liquid composition includes a base resin, a color conversion material, scatterers, and/or the like, and the color conversion material includes quantum dots. When a content (e.g., amount) of the quantum dots or the scatterers within the composition is excessively (or substantially) increased, the viscosity of the composition increases, and thus it is not easy to provide the composition through inkjet printing or dispensing. In contrast, because the second light control part CCP2 according to one or more embodiments includes the AIGS quantum dots having a relatively greater molar extinction coefficient, it is possible to reduce a weight (wt %) of the quantum dots and to increase a weight (wt %) of the scatterers by the reduced weight (wt %) of the quantum dots in the composition for forming the second light control part CCP2, thereby maintaining the WAD at a favorable level.

The first light control part CCP1, the second light control part CCP2, and the third light control part CCP3 may respectively include base resins BR1, BR2, and BR3. The first light control part CCP1 may include the first color conversion material CA1 and the scatterers SP dispersed in the first base resin BR1. The second light control part CCP2 may include the second color conversion material CA2 and the scatterers SP dispersed in the second base resin BR2. The third light control part CCP3 may include the scatterers SP dispersed in the third base resin BR3.

The base resins BR1, BR2, and BR3 may be media in which the color conversion materials CA1 and CA2 and the scatterers SP are dispersed, and may be composed of one or more suitable resin compositions generally referred to as a binder. For example, the base resins BR1, BR2, and BR3 may be an acylate-based resin, a urethane-based resin, a silicone-based resin, an epoxy-based resin, and/or the like. The base resins BR1, BR2, and BR3 may be transparent. The first base resin BR1, the second base resin BR2, and the third base resin BR3 may be the same or different from each other.

The color filter layer CFL may be arranged on the light control layer CCL. The color filter layer CFL may include first to third filters CF1, CF2, and CF3. The first to third filters CF1, CF2, and CF3 may be arranged so as to respectively correspond to the first to third light control parts CCP1, CCP2, and CCP3 of the light control layer CCL. The first filter CF1 may overlap the first light control part CCP1, the second filter CF2 may overlap the second light control part CCP2, and the third filter CF3 may overlap the third light control part CCP3. The first filter CF1 may be configured to transmit the first light, the second filter CF2 may be configured to transmit the second light, and the third filter CF3 may be configured to transmit source light. For example, the first filter CF1 may be a red filter, the second filter CF2 may be a green filter, and the third filter CF3 may be a blue filter. The first to third filters CF1, CF2, and CF3 may be arranged to respectively correspond to the first to third pixel regions PXA-R, PXA-G, and PXA-B. For example, at least some of the first to third filters CF1, CF2, and CF3 may overlap in the light-blocking region NPXA.

The first to third filters CF1, CF2, and CF3 may each include a polymer photosensitive resin and a pigment or a dye. The first filter CF1 may include a red pigment or dye, the second filter CF2 may include a green pigment or dye, and the third filter CF3 may include a blue pigment or dye. However, one or more embodiments of the present disclosure is not limited thereto, and the third filter CF3 may not include a pigment or a dye (e.g., may exclude any pigment or dye). The third filter CF3 may include a polymer photosensitive resin and may not include a pigment or a dye (e.g., may exclude any pigment or dye). The third filter CF3 may be transparent. The third filter CF3 may be formed of a transparent photosensitive resin.

In one or more embodiments, the first filter CF1 and the second filter CF2 may be yellow filters. The first filter CF1 and the second filter CF2 may be integrally provided without being separated from each other.

In one or more embodiments, the color filter layer CFL may further include a light blocking part. The light blocking part may be a black matrix. The light blocking part may be formed of an organic light-blocking material or an inorganic light-blocking material which includes a black pigment or a black dye. The light blocking part may function to prevent or reduce light leakage and define boundaries between the adjacent filters CF1, CF2, and CF3.

The upper substrate BL may be a member which provides a base surface on which the color filter layer CFL is arranged. The upper substrate BL may be a glass substrate, a metal substrate, a plastic substrate, and/or the like. However, one or more embodiments of the present disclosure is not limited thereto, and the upper substrate BL may be an inorganic layer, an organic layer, or a composite material layer. Unlike what is illustrated, the upper substrate BL may not be provided. In one or more embodiments, a functional layer such as an anti-reflection layer, an anti-fingerprint layer, and a hard coating layer may be further arranged on the upper substrate BL.

A first barrier layer BFL1, a filling layer FML, a second barrier layer BFL2, and a low-refractive-index layer LR may be provided between the light control layer CCL and the color filter layer CFL. The first barrier layer BFL1 may be provided between the light control layer CCL and the filling layer FML. The second barrier layer BFL2 may be provided between the filling layer FML and the low-refractive-index layer LR. Unlike what is illustrated, at least one selected from among the first barrier layer BFL1, the filling layer FML, the second barrier layer BFL2, and the low-refractive-index layer LR may not be provided (e.g., excluded).

The first and second barrier layers BFL1 and BFL2 may function to prevent or reduce infiltration of moisture and/or oxygen. The first barrier layer BFL1 may be arranged on the light control parts CCP1, CCP2, and CCP3 and be configured to block the light control parts CCP1, CCP2, and CCP3 from being exposed to moisture and/or oxygen. The first barrier layer BFL1 may cover the light control parts CCP1, CCP2, and CCP3.

The first and second barrier layers BFL1 and BFL2 may each include at least one inorganic layer. For example, the first and second barrier layers BFL1 and BFL2 may be formed of an inorganic material. For example, the first and second barrier layers BFL1 and BFL2 may include (e.g., may be formed of) silicon nitride, aluminum nitride, zirconium nitride, titanium nitride, hafnium nitride, tantalum nitride, silicon oxide, aluminum oxide, titanium oxide, tin oxide, cerium oxide, and silicon oxynitride, or a metal foil, and/or the like, having a certain degree of light transmittance. In one or more embodiments, the first and second barrier layers BFL1 and BFL2 may each further include an organic film. The first and second barrier layers BFL1 and BFL2 may each have a single- or multi-layered structure.

The filling layer FML may be filled between the light control layer CCL and the color filter layer CFL. The filling layer FML may function as a buffer. The filling layer FML may perform an impact absorbing function, and/or the like, and increase a strength of the display device DD. The filling layer FML may be formed from a filling resin including a polymer resin. For example, the filling layer FML may be formed from a filling layer resin including an acylate-based resin, or an epoxy-based resin, and/or the like. Unlike what is illustrated, the filling layer FML may not be provided.

The low-refractive-index layer LR may be arranged on the light control layer CCL and be configured to block the light control parts CCP1, CCP2, and CCP3 from being exposed to moisture and/or oxygen. Additionally, the low-refractive-index layer LR may be arranged between the light control parts CCP1, CCP2, and CCP3 and the filters CF1, CF2, and CF3, and may function as an optical functional layer which increases light extraction efficiency or prevents reflected light from entering the light control layer CCL, and/or the like. The low-refractive-index layer LR may have a lower refractive index than a layer adjacent thereto.

The low-refractive-index layer LR may include at least one inorganic layer. For example, the low-refractive-index layer LR may include (e.g., may be formed of) silicon nitride, aluminum nitride, zirconium nitride, titanium nitride, hafnium nitride, tantalum nitride, silicon oxide, aluminum oxide, titanium oxide, tin oxide, cerium oxide, and silicon oxynitride, or a metal foil, and/or the like, having a certain degree of light transmittance. However, one or more embodiments of the present disclosure is not limited thereto, and the low-refractive-index layer LR may include an organic film. For example, the low-refractive-index layer LR may have a structure in which a plurality of hollow particles are dispersed in an organic polymer resin. The low-refractive-index layer LR may have a single- or multi-layered structure.

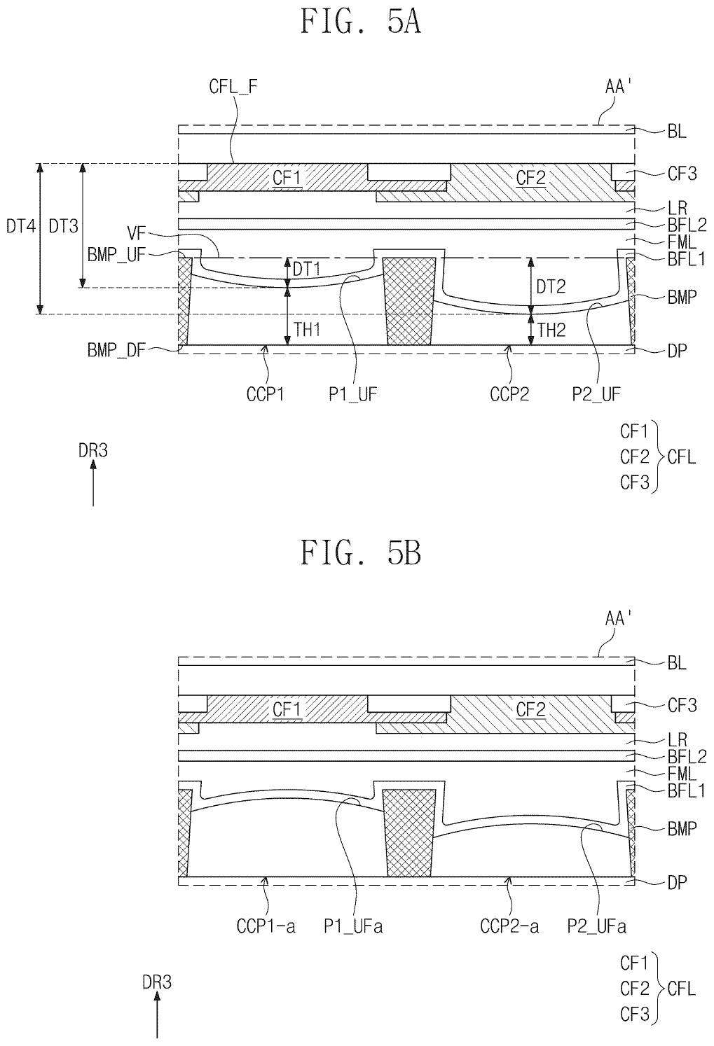

FIG. 5A is an enlarged cross-sectional view of region AA′ of FIG. 4. For convenience of description, FIG. 5A illustrates components of the region AA′ while not providing the base resins BR1 and BR2, the color conversion materials CA1 and CA2, and the scatterers SP.

Referring to FIG. 5A, the first light control part CCP1 and the second light control part CCP2 may be spaced and/or apart (e.g., spaced apart or separated) from each other with the partition wall BMP therebetween in one direction normal (e.g., perpendicular) to the thickness direction DR3. The partition wall BMP may include a lower surface BMP_DF adjacent to the display panel DP and an upper surface BMP_UF spaced and/or apart (e.g., spaced apart or separated) from the display panel DP with the lower surface BMP_DF therebetween. FIG. 5A illustrates a reference surface (e.g., an imaginary reference surface) VF, and the imaginary reference surface VF is referred to as a surface parallel to the upper surface BMP_UF of the partition wall BMP.

The second maximum distance DT2 from the imaginary reference surface VF to the second light control part CCP2 may be greater than the first maximum distance DT1 from the imaginary reference surface VF to the first light control part CCP1. The first maximum distance DT1 and the second maximum distance DT2 are referred to as the maximum values of distances parallel to the thickness direction DR3. The minimum thickness TH2 of the second light control part CCP2 may be smaller than the minimum thickness TH1 of the first light control part CCP1. The second light control part CCP2 may be formed to have a smaller thickness than the first light control part CCP1. Accordingly, the second maximum distance DT2 may be greater than the first maximum distance DT1.

FIG. 5A illustrates that the first and second light control parts CCP1 and CCP2 respectively have upper surfaces P1_UF and P2_UF which are convex downward (or concave upward) in the thickness direction DR3. The upper surface P1_UF of the first light control part CCP1 may not be flat. The minimum thickness TH1 of the first light control part CCP1 including the upper surface P1_UF which is convex downward may be a thickness at a central portion spaced and/or apart (e.g., spaced apart or separated) from the partition wall BMP. In the first light control part CCP1 including the upper surface P1_UF which is convex downward, the thickness at an edge portion adjacent to the partition wall BMP may be greater than the thickness at the central portion spaced and/or apart (e.g., spaced apart or separated) from the partition wall BMP. In one direction normal (e.g., perpendicular) to the thickness direction DR3, the central portion of the first light control part CCP1 may be spaced and/or apart (e.g., spaced apart or separated) from the partition wall BMP with the edge portion of the first light control part CCP1 therebetween. That is, the thickness of the first light control part CCP1 may gradually increase from the central portion of the first light control part CCP1 to the edge portion of the first light control part CCP1 due to the convex downward shape.

The upper surface P2_UF of the second light control part CCP2 may not be flat. The minimum thickness TH2 of the second light control part CCP2 including the upper surface P2_UF which is convex downward may be a thickness at a central portion spaced and/or apart (e.g., spaced apart or separated) from the partition wall BMP. In the second light control part CCP2 including the upper surface P2_UF which is convex downward, the thickness at an edge portion adjacent to the partition wall BMP may be greater than the thickness at the central portion spaced and/or apart (e.g., spaced apart or separated) from the partition wall BMP. In one direction normal (e.g., perpendicular) to the thickness direction DR3, the central portion of the second light control part CCP2 may be spaced and/or apart (e.g., spaced apart or separated) from the partition wall BMP with the edge portion of the second light control part CCP2 therebetween. That is, the thickness of the second light control part CCP2 may gradually increase from the central portion of the second light control part CCP2 to the edge portion of the second light control part CCP2 due to the convex downward shape.

According to a relative visibility curve, green light corresponds to light having high impacts on reflectance which deteriorates display quality of a display device. Human eyes have the maximum visibility with respect to light having a wavelength of about 555 nm, a ratio of visibility with respect to light having another wavelength (about 380 nm to about 760 nm) if (e.g., when) the maximum visibility is set to 1 is referred to as a relative visibility, and a relative visibility curve shows relative visibilities with a curved line.

In the filling layer FML, the thickness of the first region overlapping the second light control part CCP2 may be greater than the thickness of the second region overlapping the first light control part CCP1. The first region of the filling layer FML which overlaps the second light control part CCP2 and is formed to have a relatively smaller thickness TH2 may have a relatively greater thickness. In the filling layer FML, the first region arranged on the second light control part CCP2 has a relatively greater thickness, and thus green light reflectance may be reduced. As the green light passes through the first region having a relatively greater thickness in the filling layer FML, a degree of absorbing the green light in the filling layer FML may be increased, and reflectance which deteriorates display quality may be reduced.

The second light control part CCP2 is formed to have a relatively smaller thickness TH2, but includes the AIGS quantum dots having a relatively greater molar extinction coefficient, and a relatively greater weight (wt %) of the scatterers SP. Therefore, excellent or suitable light conversion properties may be exhibited, and the WAD may be maintained at a favorable level. As a result, in one or more embodiments, the display device DD (see FIG. 4) including the second light control part CCP2 may exhibit excellent or suitable display quality.

As described above, the first to third light control parts CCP1, CCP2, and CCP3 (see FIG. 4) may be formed by providing a liquid composition. The first and second light control parts CCP1 and CCP2 formed by providing a liquid composition may respectively have the upper surfaces P1_UF and P2_UF, which have a concave or convex shape in the thickness direction DR3. FIG. 5A illustrates that the respective upper surfaces P1_UF and P2_UF of the first and second light control parts CCP1 and CCP2 have a convex downward (or concave upward) shape in the thickness direction DR3. In this case, ‘downward’ refers to a direction of getting farther away from the display surface DD-IS (see FIG. 1). Also, the description made above may be similarly applied to the third light control part CCP3 illustrated in FIG. 4.

The fourth maximum distance DT4 from one surface CFL_F of the color filter layer CFL to the second light control part CCP2 may be greater than the third maximum distance DT3 from one surface CFL_F of the color filter layer CFL to the first light control part CCP1. The one surface CFL_F of the color filter layer CFL may be flat. The one surface CFL_F of the color filter layer CFL may be a flat surface which is either an upper surface or a lower surface of the color filter layer CFL. In FIG. 5A, the one surface CFL_F of the color filter layer CFL may be the upper surface of the color filter layer CFL. In FIG. 5A, the one surface CFL_F of the color filter layer CFL may be a surface adjacent to the upper substrate BL. The third maximum distance DT3 and the fourth maximum distance DT4 are referred to as the maximum values of distances parallel to the thickness direction DR3. As described above, the minimum thickness TH2 of the second light control part CCP2 may be smaller than the minimum thickness TH1 of the first light control part CCP1. Accordingly, the fourth maximum distance DT4 may be greater than the third maximum distance DT3.

FIG. 5B is a cross-sectional view of region AA′ according to one or more embodiments of the present disclosure. Hereinafter, with regard to the descriptions of FIG. 5B, the contents duplicated with those described with the references to FIGS. 1 to 5A will not be explained again, and the following description will be mainly focused on the differences.

FIG. 5B differs from FIG. 5A in that first and second light control parts CCP1-a and CCP2-a have different shapes. Unlike FIG. 5A, FIG. 5B illustrates that respective upper surfaces P1_UFa and P2_UFa of the first and second light control parts CCP1-a and CCP2-a have a convex upward (or concave downward) shape in the thickness direction DR3. In this case, ‘upward’ refers to a direction of getting closer to the display surface DD-IS (see FIG. 1).

In the first light control part CCP1-a having a convex upward shape in the thickness direction DR3, the thickness at a central portion may be greater than the thickness at an edge portion. In one direction normal (e.g., perpendicular) to the thickness direction DR3, the central portion of the first light control part CCP1-a may be spaced and/or apart (e.g., spaced apart or separated) from the partition wall BMP with the edge portion of the first light control part CCP1-a therebetween. That is, the thickness of the first light control part CCP1-a may gradually decrease from the central portion of the second light control part CCP1-a to the edge portion of the second light control part CCP1-a due to the convex upward shape.

In the second light control part CCP2-a having a convex upward shape in the thickness direction DR3, the thickness at a central portion may be greater than the thickness at an edge portion. In one direction normal (e.g., perpendicular) to the thickness direction DR3, the central portion of the second light control part CCP2-a may be spaced and/or apart (e.g., spaced apart or separated) from the partition wall BMP with the edge portion of the second light control part CCP2-a therebetween. That is, the thickness of the second light control part CCP2-a may gradually decrease from the central portion of the second light control part CCP2-a to the edge portion of the second light control part CCP2-a due to the convex upward shape.

In the context of the present disclosure and unless defined otherwise, “gradually” refers to a smooth and continuous change in thickness from one point to another. Specifically, it describes how the thickness of the first light control part CCP1 and the second light control part CCP2 changes due to their shapes.

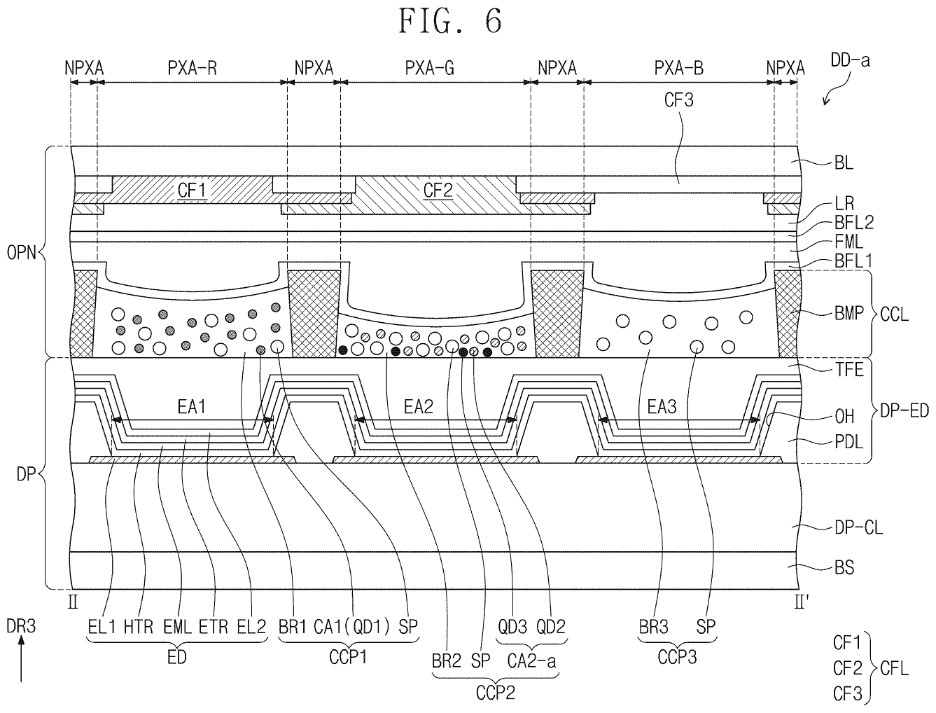

FIGS. 6 to 8 are cross-sectional views of a display device according to one or more embodiments of the disclosure. Hereinafter, with regard to the descriptions of FIGS. 6 to 8, the contents duplicated with those described with the references to FIGS. to 5B will not be explained again, and the following description will be mainly focused on the differences.

In one or more embodiments, a second color conversion material CA2-a may further include at least one of a green dye or a multi-component quantum dot containing In and P. Compared to the display device DD illustrated in FIG. 4, a display device DD-a illustrated in FIG. 6 differs from the display device DD in that the second color conversion material CA2-a further includes third quantum dots QD3. The third quantum dot QD3 may be a green quantum dot. The third quantum dot QD3 may be a multi-component quantum dot containing In and P. The description of the above-described quantum dots may be similarly applied to the third quantum dots QD3. However, this is exemplarily illustrated, and the second color conversion material CA2-a may further include a green color conversion material suitable to those in the art. In this case, the green color conversion material is a material converting source light into green light.

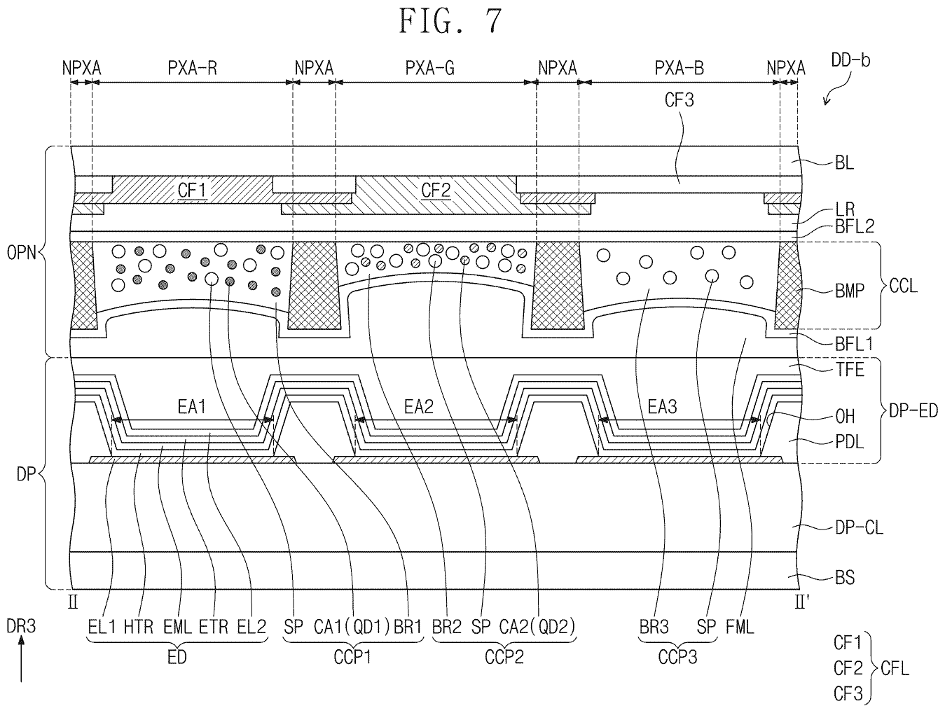

Compared to the display device DD illustrated in FIG. 4, a display device DD-b illustrated in FIG. 7 differs from the display device DD in that the position of the filling layer FML is changed. Additionally, compared to the display device DD illustrated in FIG. 4, the display device DD-b illustrated in FIG. 7 differs from the display device DD in that the position of the first barrier layer BFL1 is changed and the light control layer CCL has a different shape.

Referring to FIG. 7, the filling layer FML may be arranged between a display panel DP and the light control layer CCL. The filling layer FML may be arranged between a display element layer DP-ED and the light control layer CCL. The first barrier layer BFL1 may be arranged between the light control layer CCL and the filling layer FML.

In the above-described display device DD illustrated in FIG. 4, the light control layer CCL may be formed on the display panel DP as a base surface. For example, in the display device DD illustrated in FIG. 4, the light control layer CCL may be formed by providing a material (for example, liquid composition) for forming the light control layer CCL on one surface of the display panel DP. For example, the one surface of the display panel DP may be an upper surface of an encapsulation layer TFE adjacent to the display surface DD-IS (see FIG. 1).

In contrast, in the display device DD-b illustrated in FIG. 7, the light control layer CCL may be formed on a second barrier layer BFL2 as a base surface. For example, the light control layer CCL illustrated in FIG. 7 may be formed by providing a material (for example, liquid composition) for forming the light control layer CCL on one surface of the second barrier layer BFL2. For example, the one surface of the second barrier layer BFL2 may be a lower surface of the second barrier layer BFL2 spaced and/or apart (e.g., spaced apart or separated) from the display surface DD-IS (see FIG. 1).

Accordingly, the light control layer CCL illustrated in FIG. 4 may have a shape different from that of the light control layer CCL illustrated in FIG. 7. In the light control layer CCL illustrated in FIG. 4, the first to third light control parts CCP1, CCP2, and CCP3 may have a convex downward (or concave upward) shape, and in the light control layer CCL illustrated in FIG. 7, the first to third light control parts CCP1, CCP2, and CCP3 may have a convex upward (or concave downward) shape. In this case, ‘downward’ refers to a direction of getting farther away from the display surface DD-IS (see FIG. 1), and ‘upward’ refers to a direction of getting closer to the display surface DD-IS (see FIG. 1).

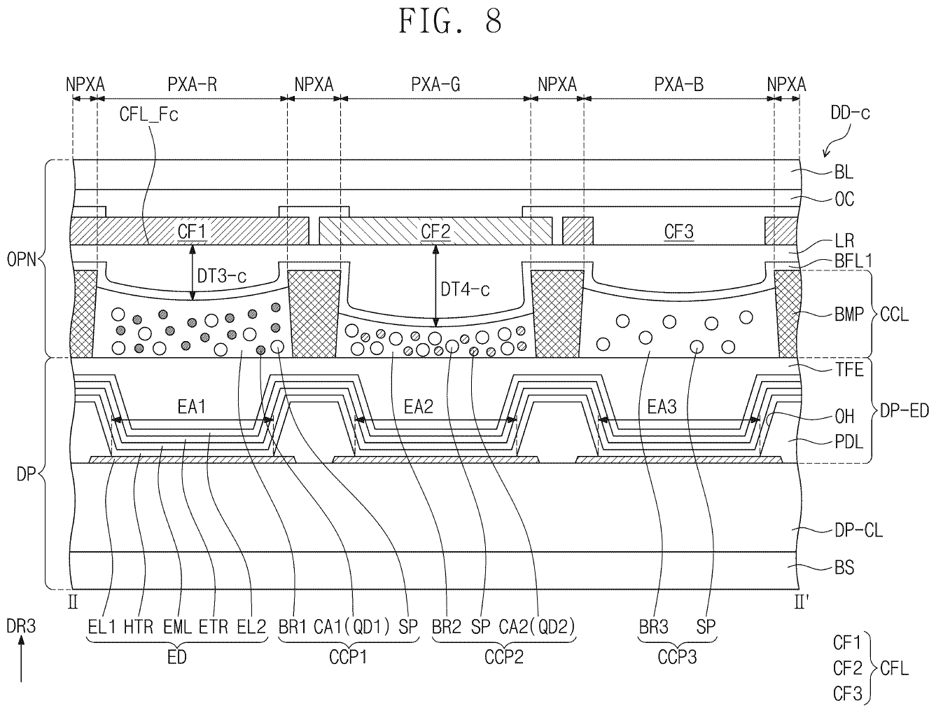

Compared to the display device DD illustrated in FIG. 4, a display device DD-c illustrated in FIG. 8 differs from the display device DD in that the filling layer FML (see FIG. 4) and the second barrier layer BFL2 (see FIG. 4) are not included and the overcoat layer OC is further included. Additionally, compared to the display device DD illustrated in FIG. 4, the display device DD-c illustrated in FIG. 8 differs from the display device DD in that the color filter layer CFL has a different shape.

Referring to FIG. 8, the light control layer CCL may be directly arranged on the display panel DP. The first barrier layer BFL1 may be arranged on the light control layer CCL, the low-refractive-index layer LR may be arranged on the first barrier layer BFL1, and the color filter layer CFL may be arranged on the low-refractive-index layer LR. The color filter layer CFL may be formed on the low-refractive-index layer LR as a base surface. Accordingly, a lower surface CFL_Fc of the color filter layer CFL may be flat.

In one or more embodiments, the fourth maximum distance DT4-c may be greater than the third maximum distance DT3-c. The third maximum distance DT3-c may be the maximum distance from one surface CFL_Fc of the color filter layer CFL to the first light control part CCP1. The fourth maximum distance DT4-c may be the maximum distance from the one surface CFL_Fc of the color filter layer CFL to the second light control part CCP2. The third and fourth maximum distances DT3-c and DT4-c are referred to as the maximum values of a distance parallel to the thickness direction DR3. The one surface CFL_Fc of the color filter layer CFL may be flat. The one surface CFL_Fc of the color filter layer CFL may be a lower surface of the color filter layer CFL spaced and/or apart (e.g., spaced apart or separated) from the upper substrate BL.

The overcoat layer OC may be arranged on the color filter layer CFL. The overcoat layer OC may be a planarization layer. The overcoat layer OC may cover a stepped portion of the color filter layer CFL arranged the overcoat layer OC, and provide a flat surface. An upper surface of the overcoat layer OC may be flat. The overcoat layer OC may include an organic material.

The upper substrate BL may be arranged on the overcoat layer OC. Unlike what is illustrated, the upper substrate BL may not be provided.

Hereinafter, a display device including a light control part according to one or more embodiments of the present disclosure will be described in more detail with reference to Comparative Example and Experimental Example. In addition, one or more embodiments to be illustrated are described as examples for ease of understanding the present disclosure, and a scope of the present disclosure is not limited thereto.

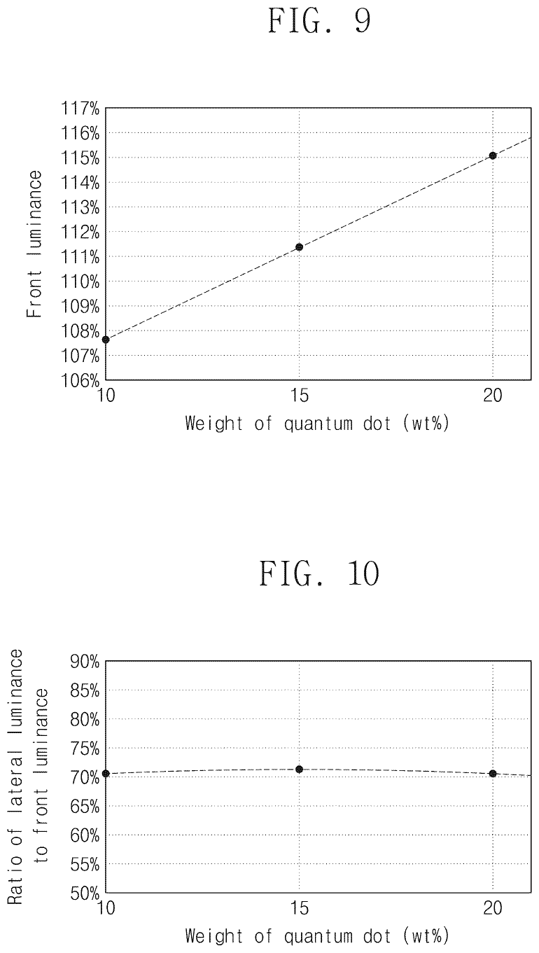

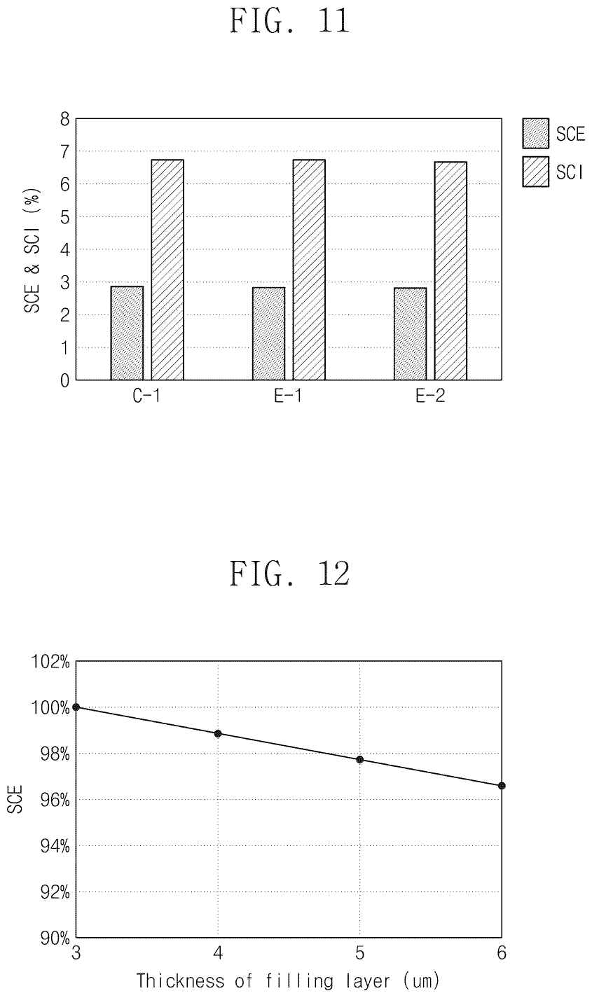

FIGS. 9 to 12 are graphs showing evaluation results of optical properties of a display device according to Comparative Example and a display device according to Experimental Example. FIGS. 9 and 10 are graphs showing optical properties evaluated using a spectroradiometer SR-3AR (made by TOPCON Technohouse Corporation). FIG. 11 is a graph showing optical properties evaluated using a spectroscopic colorimeter CM-3600D (made by Konica Minolta). FIG. 12 is a graph obtained by performing simulation.

FIG. 9 is a graph showing a front luminance versus a content (e.g., amount) of green quantum dots, in which the front luminance is shown as a relative value of a luminance of the display device of Experimental Example with respect to 100% of a luminance of the display device of Comparative Example. The front luminance is referred to as a luminance if (e.g., when) the display device is viewed from a front surface.

In FIG. 9, the display device of Comparative Example contains green quantum dots in an amount of about 41 wt %, and TiO₂ in an amount of about 4 wt % with respect to 100 wt % of the total weight of the green light control part. In the display device of Comparative Example, the green quantum dots are multi-component quantum dots containing In and P, and the green light control part has a minimum thickness of about 7.6 um. In the display device of Comparative Example, the thickness of the green light control part is greater than the thickness of the red light control part.

In FIG. 9, the display device of Experimental Example contains TiO₂ in an amount of about 6.5 wt % with respect to 100 wt % of the total weight of the green light control part, and the green light control part has a minimum thickness of about 5 μm. In the display device of Experimental Example, the thickness of the green light control part is smaller than the thickness of the red light control part. In the display device of Experimental Example, the green light control part includes AIGS quantum dots as green quantum dots, and as shown on a horizontal axis of the graph, a weight (wt %) of the quantum dots is changed. The weight (wt %) of the quantum dot shown on the horizontal axis of the graph is a weight with respect to 100 wt % of the total weight of the green light control unit.

In FIG. 9, the display device of Experimental Example includes the green light control part according to one or more embodiments, and compared to the display device of Comparative Example, the green light control part includes a relatively smaller weight (wt %) of a color conversion material (that is, quantum dots). Additionally, the display device of Experimental Example includes the green light control part having a relatively smaller thickness, and the green light control part includes a relatively greater weight (wt %) of scatterers (that is, TiO₂).

Referring to FIG. 9, it may be confirmed that the display device, of Experimental Example, including a green light control part having a relatively smaller weight (wt %) of green quantum dots, a greater weight (wt %) of scatterers, and a greater thickness exhibits more excellent or suitable luminance than the display device of Comparative Example. As illustrated above, in FIG. 9, the display device of Experimental Example includes the green light control part according to one or more embodiments. The green light control part according to one or more embodiments includes a relatively smaller weight (wt %) of a color conversion material, and a relatively greater weight (wt %) of scatterers, and is formed to have a relatively smaller thickness. Therefore, it may be seen that the display device including the green light control part according to one or more embodiments exhibits excellent or suitable luminance.

FIG. 10 shows a graph showing a ratio of a lateral luminance to a front luminance according to a content (e.g., amount) of quantum dots in the display device of Experimental Example. The ratio of a lateral luminance to a front luminance is referred to as a ratio obtained by comparing, with brightness from a front surface, brightness at a point having an angle of about 60° with respect to the front surface.

In FIG. 10, the display device of Experimental Example includes the green light control part same as the display device of Experimental Example described with reference to FIG. 9. The display device of Comparative Example includes the green light control part same as the display device of Comparative Example described with reference to FIG. 9, and it is confirmed that in the display device of Comparative Example, a ratio of a lateral luminance to a front luminance is about 71%.

Referring to FIG. 10, it may be confirmed that in the display device of Experimental Example, a ratio of a lateral luminance to a front luminance is about 70% to about 72%, and in the display device of Experimental Example, and a ratio of a lateral luminance to a front luminance in the display device of Experimental Example is similar to that of the display device of Comparative Example. As illustrated above, in FIG. 10, the display device of Experimental Example includes the green light control part according to one or more embodiments. Accordingly, it may be confirmed that the display device including the green light control part according to one or more embodiments exhibits a favorable ratio of a lateral luminance to a front luminance.

FIG. 11 is a graph showing a specular component excluded (SCE) reflectance and a specular component included (SCI) reflectance in each of the display devices of Experimental Example and Comparative Example. In FIG. 11, C-1 represents the display device according to Comparative Example, and E-1 and E-2 represent the display devices according to Experimental Examples. C-1 represents the display device same as the display device, of Comparative Example, described with reference to FIGS. 9 and 10.

Table 1 shows a thickness of a green light control part, a type (kind) of a green quantum dot, a weight of a green quantum dot, and a weight of TiO₂ included in the display device of each of C-1, E-1, and E-2 illustrated in FIG. 11. In Table 1, the weight of the green quantum dots and the weight of TiO₂ are based on the total weight of the green light control part.

TABLE 1

| | C-1 | E-1 | E-2 |
|---|---|---|---|
| Thickness of Green | 7.6 | 5 | 7.6 |
| light control part [μm] | | | |
| Type of Green | Multi-component | AIGS | AIGS |
| quantum dot | quantum dot | quantum | quantum |
| | including In and P | dot | dot |
| Weight of Green | 41 | 15 | 15 |
| quantum dot (wt %) | | | |
| Weight of TiO₂ (wt %) | 4 | 6.5 | 4 |

Referring to Table 1, compared to the display device of C-1, the display devices of E-1 and E-2 include a relatively smaller weight of green quantum dots. Compared to the display device of C-1, the display device of E-1 includes a green light control part having a relatively smaller thickness, and a relatively greater weight of TiO₂. The display devices of E-1 and E-2 include the green light control parts according to one or more embodiments.

Table 2 shows specific records of the SCE reflectance and the SCI reflectance shown in the graph of FIG. 11.

TABLE 2

| | C-1 | E-1 | E-2 |
|---|---|---|---|
| SCE(%) | 2.87 | 2.83 | 2.81 |
| SCI(%) | 6.74 | 6.74 | 6.67 |

Referring to Table 2, it may be confirmed that the display devices of E-1 and E-2 have the SCE reflectance and the SCI reflectance equal to or less than that of the display device of C-1. It may be confirmed that the reflectance of the display device of each of E-1 and E-2 is equal to or further improved than the reflectance of the display device of C-1. As described above, the display devices of E-1 and E-2 include the green light control parts according to one or more embodiments. Therefore, it may be confirmed that the display device including the green light control part according to one or more embodiments exhibits excellent or suitable reflectance.

FIG. 12 is a graph showing the SCE reflectance versus a thickness of a filling layer in a display device of Experimental Example E-3, and as illustrated in FIG. 7, the display device of Experimental Example E-3 includes the filling layer arranged between the display panel and the light control layer. In FIG. 12, the SCE reflectance is shown as a relative value of a SCE reflectance with respect to 100% of the SCE reflectance of the filling layer having a thickness of about 3 um.

Referring to FIG. 12, it may be confirmed that as a thickness of the filling layer increases, the SCE reflectance is decreased. As described above, because the green light control part according to one or more embodiments is formed to have a relatively smaller thickness, a thickness of the first region overlapping the green light control part in the filling layer may be increased. Therefore, it may be seen that the display device including the green light control part according to one or more embodiments may exhibit decreased reflectance.

In summary of the evaluation results of FIGS. 9 to 12, it may be understood that the display device including the green light control unit according to one or more embodiments exhibits the excellent or suitable luminance while maintaining favorable reflectance or having improved reflectance. Therefore, it may be confirmed that the display device including the green light control part according to one or more embodiments exhibits excellent or suitable display quality.

A display device according to one or more embodiments may include a light control layer arranged on a display panel, and the light control layer may include a red light control part and a green light control part. The red light control part may include red quantum dots, and the green light control part may include green quantum dots. The green light control part may include the green quantum dots having a molar extinction coefficient greater than that of the red quantum dots of the red light control part. The weight (wt %) of the green quantum dots with respect to 100 wt % of the total weight of the green light control part may be smaller than the weight (wt %) of the red quantum dots with respect to 100 wt % of the total weight of the red light control part. The minimum thickness of the green light control part may be smaller than the minimum thickness of the red light control part. Therefore, the display device according to one or more embodiments may have enhanced luminance and improved reflectance, thereby exhibiting excellent or suitable display quality.

A display device according to one or more embodiments may include a green light control part having a relatively small thickness, thereby exhibiting excellent or suitable display quality.

The display device, the electronic apparatus, the electronic equipment or device, a manufacturing device for the display device, the electronic apparatus, the electronic equipment or device or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

A person of ordinary skill in the art, in view of the present disclosure in its entirety, would appreciate that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Although one or more embodiments of the present disclosure have been described, it is understood that the present disclosure should not be limited to these embodiments but one or more suitable changes and modifications can be made by one ordinary skilled in the art within the spirit and scope of the present disclosure as hereinafter claimed and equivalents thereof.

Therefore, the technical scope of the present disclosure is not limited to the contents described in the detailed description of the specification, but should be determined by the claims and equivalents thereof.

What is claimed is:

1. A display device comprising:
a display panel configured to emit source light;
a light control layer on the display panel, the light control layer comprising:
a partition wall;
a green light control part comprising green quantum dots; and
a red light control part comprising red quantum dots; and
a color filter layer on the light control layer, the color filter layer comprising a first filter overlapping the red light control part and a second filter overlapping the green light control part,
wherein,
the green light control part and the red light control part are spaced from each other with the partition wall therebetween in one direction perpendicular to a thickness direction, and
in the thickness direction, a fourth maximum distance from one surface of the color filter layer to the green light control part is greater than a third maximum distance from the one surface of the color filter layer to the red light control part.

2. The display device of claim 1, wherein the green quantum dots comprise a multi-component quantum dot containing Ag, In, Ga, and S.

3. The display device of claim 1, wherein a weight (wt %) of the green quantum dots with respect to 100 wt % of the total weight of the green light control part is smaller than a weight (wt %) of the red quantum dots with respect to 100 wt % of the total weight of the red light control part.

4. The display device of claim 1, wherein the green light control part further comprises scatterers, and the scatterers are contained in an amount of about 4 wt % to about 15 wt % with respect to 100 wt % of the total weight of the green light control part.

5. The display device of claim 1, wherein the green light control part and the red light control part each further comprises scatterers, and
a weight (wt %) of the scatterers in the green light control part with respect to 100 wt % of the total weight of the green light control part is greater than a weight (wt %) of the scatterers in the red light control part with respect to 100 wt % of the total weight of the red light control part.

6. The display device of claim 5, wherein the scatterers comprise at least one selected from among TiO₂, SiO₂, BaTiO₃, BaO, ZnS, ZnO, Al₂O₃, and a hollow silica.

7. The display device of claim 1, wherein the partition wall comprises a lower surface adjacent to the display panel and an upper surface spaced from the display panel with the lower surface therebetween, and
a second maximum distance from an imaginary reference surface parallel to the upper surface of the partition wall to the green light control part in the thickness direction is greater than a first maximum distance from the reference surface to the red light control part in the thickness direction.

8. An electronic device comprising:
a display device comprising:
a display panel configured to emit source light; and
a light control layer on the display panel, and comprising:
a partition wall;
a red light control part comprising a first color conversion material; and
a green light control part comprising a second color conversion material,
wherein,
the first color conversion material comprises red quantum dots,
the second color conversion material comprises green quantum dots,
the green light control part and the red light control part are spaced apart from each other with the partition wall therebetween in one direction perpendicular to a thickness direction,
the partition wall comprises a lower surface adjacent to the display panel and an upper surface spaced apart from the display panel with the lower surface therebetween, and
a second maximum distance from a reference surface parallel to the upper surface of the partition wall to the green light control part in the thickness direction is greater than a first maximum distance from the reference surface to the red light control part in the thickness direction.

9. The electronic device of claim 8, wherein the electronic device is selected from the group consisting of a television, a monitor, an outdoor billboard, a personal computer, a laptop computer, a personal digital assistant, a car navigation unit, a game console, a smartphone, a tablet computer, and a camera.

10. An electronic device comprising:
a display device comprising:
a display panel configured to emit source light;
a light control layer on the display panel, the light control layer comprising:
a partition wall;
a green light control part comprising green quantum dots; and
a red light control part comprising red quantum dots; and
a color filter layer on the light control layer, the color filter layer comprising a first filter overlapping the red light control part and a second filter overlapping the green light control part,
wherein,
the green light control part and the red light control part are spaced from each other with the partition wall therebetween in one direction perpendicular to a thickness direction, and
in the thickness direction, a fourth maximum distance from one surface of the color filter layer to the green light control part is greater than a third maximum distance from the one surface of the color filter layer to the red light control part.
